(19) United States
(12) Patent Application Publication
(10) Pub. No.: US 2025/0372433 A1
(43) Pub. Date: Dec. 4, 2025

(54) WAFER TRANSFER DEVICE AND WAFER TRANSFER SYSTEM

(71) Applicant: SAMSUNG ELECTRONICS CO., LTD., Suwon-si (KR)

(72) Inventors: Sung-Il CHOI, Suwon-si (KR); Kyungbeom KIM, Suwon-si (KR); Seoyoung MAENG, Suwon-si (KR); Mira PARK, Suwon-si (KR); Sung Hong PARK, Suwon-si (KR); YoungTak SON, Suwon-si (KR); Younghoon SOHN, Suwon-si (KR); Yongjin CHO, Suwon-si (KR); Hong Tae CHEON, Suwon-si (KR)

(21) Appl. No.: 19/022,695

(22) Filed: Jan. 15, 2025

(30) Foreign Application Priority Data
May 29, 2024 (KR) 10-2024-0070028
Jul. 23, 2024 (KR) 10-2024-0097096

(51) Int. Cl. H01L 21/683; H01L 21/687

(52) U.S. Cl. CPC H01L 21/6838; H01L 21/68707

(57) ABSTRACT

A wafer transfer device includes a blade having a first surface configured to receive a wafer, and a vacuum pad removably secured to the blade and configured to adsorb the wafer on the blade. The blade includes a pair of arm portions extending in a first direction and that are in spaced apart parallel relationship with each other, and a support portion connecting the pair of arm portions. The vacuum pad includes a first pad portion on the support portion, and a pair of second pad portions, each second pad portion on a respective one of the pair of arm portions. The first pad portion and the pair of second pad portions define a triangle. A length of a base of the triangle formed by the pair of second pad portions is less than a length of a height of the triangle.

### CROSS-REFERENCE TO RELATED APPLICATION

This application claims priority to and the benefit of Korean Patent Application No. 10-2024-0070028 filed in the Korean Intellectual Property Office on May 29, 2024, and Korean Patent Application No. 10-2024-0097096 filed in the Korean Intellectual Property Office on Jul. 23, 2024, the disclosures of which are incorporated herein by reference in their entireties.

### BACKGROUND OF THE INVENTION

### (a) Field of the Invention

The present disclosure relates to a wafer transfer device and a wafer transfer system.

### (b) Description of the Related Art

Semiconductors are manufactured by performing a plurality of unit processes including a deposition process, a photolithography process, an oxidation process, an etching process, an ion implantation process, and a metal wiring process.

When the respective processes are finished, a wafer is to be transferred to perform subsequent processes, and a wafer transfer device for transferring the wafer without generating wafer pick-up errors is needed in this process.

From among the wafer transfer devices, there is a device for fixing a wafer on a blade by using vacuum, and the device has a structure in which a vacuum pad for vacuum-adsorbing the wafer is fixed to the blade.

Recently, as higher integration of semiconductor processes is progressed, high temperature heat is applied to the wafer and the wafer may become bent or warpage may occur. It may be difficult for conventional wafer transfer devices to stably transfer a wafer that has become bent, warped, or otherwise misshaped.

### SUMMARY OF THE INVENTION

The present disclosure describes a wafer transfer device for adjusting a position of a vacuum pad on a blade, and that is configured to stably adsorb and transfer the wafer in response to state changes of the wafer from among compression and stretch of the wafer.

The present disclosure describes a wafer transfer device for easily replacing a vacuum pad, and reducing cost by the replacement of vacuum pad by combining or separating the integrally-structured vacuum pad secured to a blade without an additional attachment member.

The present disclosure describes a wafer transfer device for providing curvature to protrusions (raised rim) where a vacuum pad contacts a wafer to increase wafer adsorption stability, and preventing a protruding wall disposed on a raised rim surface from sliding when a wafer arrives.

An embodiment of the present disclosure provides a wafer transfer device including a blade having a first surface configured to receive a wafer; and a vacuum pad removably secured to the blade and configured to adsorb the wafer to the blade. The blade includes a pair of arm portions in spaced apart, parallel relationship with each other, and a support portion connecting the pair of arm portions. The vacuum pad includes a first pad portion on the support portion, and a pair of second pad portions, each second pad portion on a respective one of the pair of arm portions. The first pad portion and the pair of second pad portions define a triangle with the first pad portion and the pair of second pad portions as three vertexes of the triangle. A length of a base of the triangle formed by the pair of second pad portions is less than a length of a height of the triangle.

Another embodiment of the present disclosure provides a wafer transfer device including a blade having a first surface configured to receive a wafer; and a vacuum pad removably secured to the blade and configured to adsorb the wafer to the blade. The vacuum pad includes a suction portion configured to adsorb the wafer, a raised rim extending circumferentially around an outer periphery of suction portion, wherein the suction portion includes a first surface and an opposite second surface, and wherein the raised rim includes a third surface that is spaced apart from the first surface of the suction portion, and an attachment portion extending outward from the suction portion second surface. Wherein the blade includes an internal bore, and wherein the attachment portion is inserted within the internal bore to removably secure the vacuum pad to the blade.

Another embodiment of the present disclosure provides a wafer transfer system including a wafer transfer device having a blade with a first surface configured to receive a wafer, and a vacuum pad configured to adsorb the wafer to the blade; a core portion configured to support the blade; and a rotation portion connected to the core portion. The blade includes a pair of arm portions in spaced apart, parallel relationship with each other. A support portion connects the pair of arm portions. The vacuum pad includes a first pad portion on the support portion, and a pair of second pad portions, each second pad portion on a respective one of the pair of arm portions. The first pad portion and the pair of second pad portions define a triangle with an apex angle formed with the first pad portion as a vertex and an angle of less than 50 degrees. The vacuum pad and the blade are removably secured together by a snap-fit, and the rotation portion is configured to rotate the blade.

According to the embodiments, a wafer may be stably transferred without generating pickup errors in response to the state change of the wafer such as warpage of the wafer.

### BRIEF DESCRIPTION OF THE DRAWINGS

FIG. 1 illustrates a conventional wafer transfer device.

FIG. 2 illustrates a wafer transfer device according to an embodiment.

FIG. 3 illustrates an arranged configuration of a vacuum pad in a wafer transfer device according to an embodiment.

FIG. 4 illustrates an adsorption effect of a wafer transfer device according to an embodiment.

FIG. 5 illustrates a combined configuration of a vacuum pad and a blade in a wafer transfer device according to another embodiment.

FIG. 6 illustrates a shape of raised rim of a vacuum pad in a wafer transfer device according to another embodiment.

FIG. 7 illustrates a step generated by a vacuum line in a wafer transfer device.

FIG. 8 illustrates removal of a step generated by a wafer transfer device according to FIG. 7.

FIG. 9 illustrates a shape of raised rim including curvature in a wafer transfer device according to another embodiment.

FIG. 10 illustrates a wafer adsorption effect by a wafer transfer device of FIG. 9.

FIG. 11 illustrates a configuration of a wafer transfer system according to an embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

The size and thickness of each configuration shown in the drawings may be arbitrarily shown for better understanding and ease of description, but the present invention is not limited thereto. The thickness of layers, films, panels, regions, etc., may be enlarged for clarity. The thicknesses of some layers and areas may be exaggerated for convenience of explanation.

Throughout this specification and the claims that follow, when it is described that an element is “coupled” to another element, the element may be “directly coupled” to the other element or “indirectly coupled” to the other element through a third element. Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

The phrase “in a plan view” means viewing an object portion from the top (i.e., from above), and the phrase “in a cross-sectional view” means viewing a cross-section of which the object portion is vertically cut from the side.

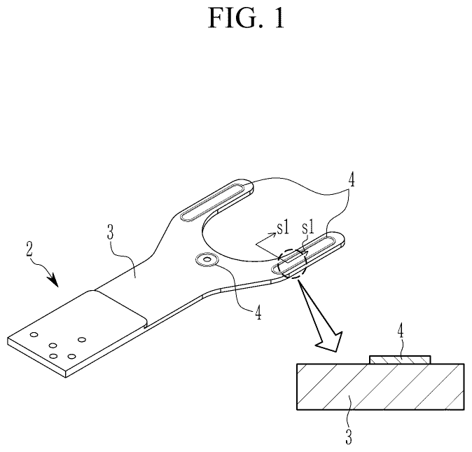

FIG. 1 illustrates a conventional wafer transfer device.

FIG. 1 illustrates a conventional wafer transfer device 2, and an enlarged drawing shown on the right illustrates a blade 3 and a vacuum pad 4 when the conventional wafer transfer device 2 is seen on a cross-section of s1.

Referring to the enlarged drawing, the conventional wafer transfer device 2 has a shape in which the vacuum pad 4 for adsorbing the wafer is adhered on the blade 3 using an adhesive.

In the case of the conventional wafer transfer device 2, the vacuum pad 4 was attached to a surface of the blade 3 by using an adhesive such as epoxy, so it was impossible or at least very difficult to separate and replace the vacuum pad 4. Thus, when the vacuum pad 4 becomes worn and a pickup error is generated, the portion of the vacuum pad 4 is not replaced and the entire blade 3 has to be replaced.

Further, when the vacuum pad 4 becomes worn, there is no reference to compare how much the vacuum pad 4 has worn. Hence, the blade 3 sometimes has to be replaced even when the vacuum pad 4 can still be used. Conversely, there are cases where the blade 3 has to be replaced when the vacuum pad 4 becomes excessively worn.

In addition, there is a problem that the adsorption capacity is reduced due to a gap occurring between the surface of the vacuum pad 4 and the wafer because of warpage of the wafer.

The vacuum pad 4 adheres to the wafer, so when seating the wafer adsorbed to the vacuum pad 4 in the stage, the wafer may be separated from the vacuum pad 4, and may bounce or slip. As a result, the wafer may not be seated in the correct position on the stage, and drop scratches may occur during the wafer separating process.

In addition, during the process for connecting a vacuum line to the blade 3 to supply vacuum to the vacuum pad 4, tape is attached to seal the vacuum line, and a step is generated between the tape portion and the surface of the blade 3. Due to the step, there is also a problem in which the threads of the wiper used in the wafer cleaning process remain on the blade 3, causing scratches to continuously occur.

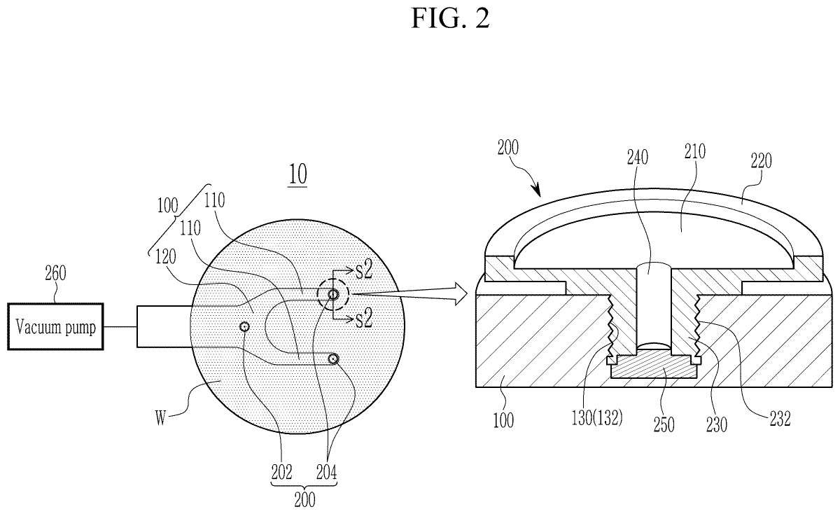

The wafer transfer device 10 (FIG. 2) according to the present disclosure is intended to improve the above-mentioned problems of the conventional wafer transfer device 2.

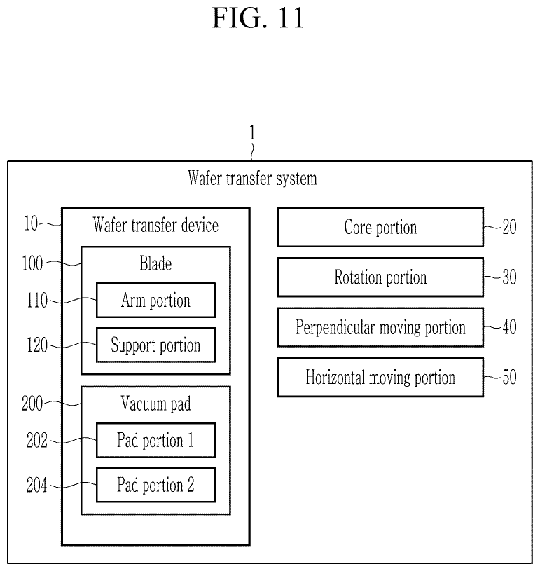

A wafer transfer device 10 and a wafer transfer system 1 (FIG. 11) including the same according to an embodiment of the present disclosure will be described in detail with reference to the drawings.

The wafer in the present disclosure may mean the wafer itself, or a stacking structure including a predetermined layer or film formed on the surface of the wafer.

Additionally, the wafer may be a wafer, or may include a wafer and at least one material film on the wafer. The material film may be an insulating layer and/or a conductive layer formed on the wafer through various methods such as deposition, coating, and plating. For example, the insulating layer may include an oxide layer, a nitride layer or an oxynitride layer, and the conductive layer may include a metal layer or a polysilicon layer. Meanwhile, the material film may also be formed on a wafer with a predetermined pattern.

FIG. 2 illustrates a wafer transfer device according to an embodiment.

As shown in FIG. 2, the wafer transfer device 10 includes a blade 100 with a first surface on which a wafer W is seated, and a vacuum pad 200 configured to be attached to the blade 100 for adsorbing the wafer W on the blade 100.

The blade 100 may include a pair of arm portions 110 spaced and arranged, and a support portion 120 for connecting the one pair of arm portions 110.

The one pair of arm portions 110 extend in a first direction, and are spaced to be arranged in parallel. The support portion 120 extends from respective sides of the one pair of arm portions 110 and connects the one pair of arm portions 110.

The vacuum pad 200 may include a first pad portion 202 arranged on the support portion 120, and one pair of second pad portions 204 arranged on the one pair of arm portions 110. The one pair of second pad portions 204 may be arranged in a second direction that is orthogonal to the first direction.

As shown in FIG. 2, arranged positions of three vacuum pads 200 may configure a triangle.

Here, a side formed by the one pair of second pad portions 204 arranged on the arm portion 110 is set to be a base of a triangle, and a length (vertical distance) to the first pad portion 202 of the support portion 120 from the base of the triangle is set to be a height of the triangle.

Regarding the wafer transfer device 10, in the case of a virtual triangle in which the first pad portion 202 and the one pair of second pad portions 204 are defined as three vertexes, the length of the base of the triangle configured by the one pair of second pad portions 204 is equal to or less than the length of the height of the triangle. That is, the height of the triangle is longer than the base.

FIG. 2 illustrates a floor plan of the wafer transfer device 10 according to the present disclosure, and illustrates a cross-sectional view of the wafer transfer device 10 with respect to s2. The enlarged drawing illustrates shapes of the blade 100 and the vacuum pad 200 and a mutual combined structure.

The vacuum pad 200 may include an inhaling or suction portion 210 for adsorbing the wafer W while spaced from the wafer W, a raised rim 220 surrounding the suction portion 210 and having a first surface further protruding than a first surface of the suction portion 210, an attachment portion 230 arranged in a center portion of the suction portion 210 and protruding toward a second surface, and a vacuum hole or aperture 240 penetrating the attachment portion 230 from the suction portion 210.

A material of the vacuum pad 200 may include a polybenzimidazole (PBI)-based plastic material, for example.

A distance of the suction portion 210 spaced from the wafer W may be a distance that is close to the protruding height of the raised rim 220.

The attachment portion 230 protrudes toward the second surface, that is, an opposite direction of the raised rim 220 protruding to the first surface from the suction portion 210 (i.e., the attachment portion 230 and the raised rim 220 extend in respective opposite directions from the suction portion).

The vacuum hole 240 may be connected to a vacuum path 250 arranged on the blade 100. FIG. 2 illustrates that the entire vacuum path 250 is installed in the blade 100. However, the arranged structure of the vacuum path 250 is not limited to the structure shown in FIG. 2.

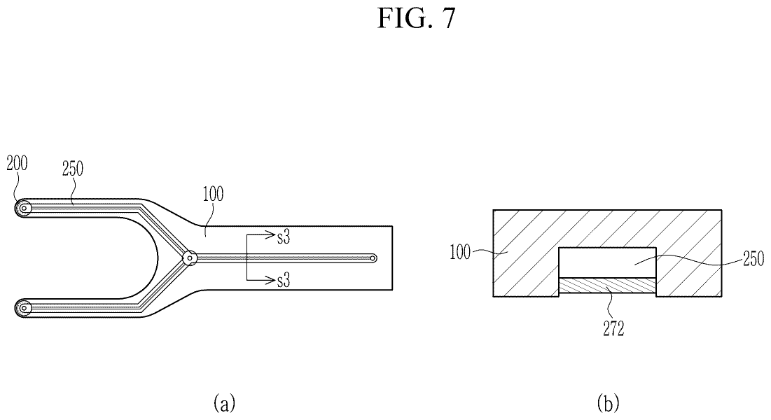

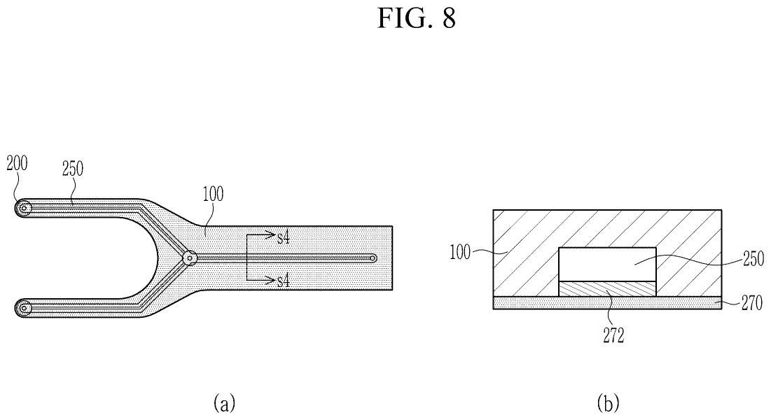

Regarding the arranged structure of the vacuum path 250, in general, as shown in FIG. 7 and FIG. 8, a first surface is arranged toward an inside of the blade 100, and a second surface is exposed toward an outside of the blade 100.

The wafer transfer device 10 may further include a vacuum pump 260 for supplying a vacuum pressure to the vacuum aperture 240 through the vacuum path 250.

Regarding the wafer transfer device 10, the vacuum pad 200 secured to the blade 100 has an integrated structure. The vacuum pad 200 includes the protruding attachment portion 230 on the second side that extends in a direction toward the blade 100. As described, the vacuum pad 200 represents a structure in which the integrally-structured attachment portion 230 is secured to the blade 100. That is, the vacuum pad 200 is configured to be removably secured to the blade 100 without an additional attachment member so it is easy to replace the vacuum pad 200.

Regarding the conventional wafer transfer device 2 shown in FIG. 1, the vacuum pad 4 is attached to the surface of the blade 3 using an adhesive such as epoxy.

Differing from this, the wafer transfer device 10 does not use the adhesive when the vacuum pad 200 is secured to the blade 100. There is also a difference in that no attachment member to be additionally attached is added.

The blade 100 may include an internal bore 130 into which the attachment portion 230 extends.

Regarding the wafer transfer device 10, the vacuum pad 200 may be secured to the blade 100 by securing the attachment portion 230 within the internal bore 130.

As shown in FIG. 2, the attachment portion 230 disposed in the center of the vacuum pad 200 is secured to the blade 100 so a circumferential portion of the vacuum pad 200, that is, a portion that is exclusive of the attachment portion 230 has freedom.

The above-described fastening-type attachment structure of the wafer transfer device 10 improves the gap of bending stiffness by 92.9%, compared to the conventional structure using an adhesive.

This signifies that the freedom of motion of the circumferential portion including the raised rim 220 contacting the wafer W increases. That is, when the shape of the wafer W changes such as tension or compression, a contact area of the wafer W and the raised rim 220 is maximally maintained.

Depending on embodiments, a screw thread 232 may be included in an external circumference of the attachment portion 230, and a spiral groove 132 combined to the screw thread 232 may be included inside the internal bore 130. The vacuum pad 200 may be removably secured to the blade 100 by combining the screw thread 232 and the spiral groove 132 (i.e., the vacuum pad 200 is threadingly secured to the internal bore 130).

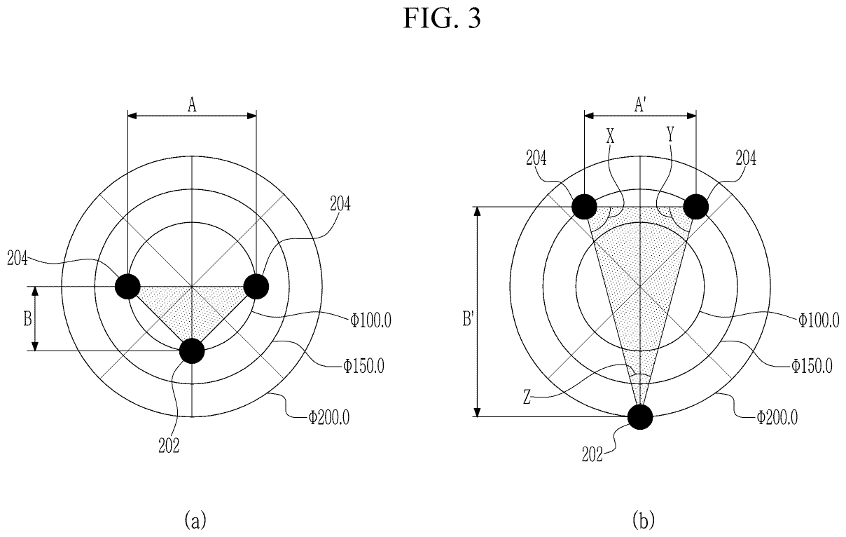

FIG. 3 illustrates an arranged configuration of a vacuum pad in a wafer transfer device according to an embodiment.

FIG. 3 (a) illustrates a triangle configured by one first pad portion 202 and a pair of second pad portions 204, showing the case when the base A of the triangle is longer than the height B. FIG. 3 (b) illustrates that the base A′ of the triangle is shorter than the height B′.

The arrangement of the vacuum pad 200 corresponds to FIG. 3 (b), and FIG. 3 (a) is shown to be compared with FIG. 3 (b).

Referring to FIG. 3 (a), the side formed by the one pair of second pad portions 204 corresponds to the base A, and the vertical distance to the first pad portion 202 from the base A corresponds to the height B. FIG. 3 (a) shows that A is longer than B.

The three illustrated concentric circles represent diameters that are 100 mm, 150 mm, and 200 mm, respectively.

The arrangement of the vacuum pad 200 corresponds to the case when the height B′ is longer than the base A′ that is the side formed by the one pair of second pad portions 204, as shown in FIG. 3 (b).

The length ratio of base A′ to height B′ may be equal to or greater than 1.4 and equal to or less than 1.8. Preferably, the ratio may be 1.67.

The wafer transfer device 10 arranges the vacuum pad 200 so that the height B′ may become longer than the base A′ in the triangle in which the vacuum pad 200 is arranged.

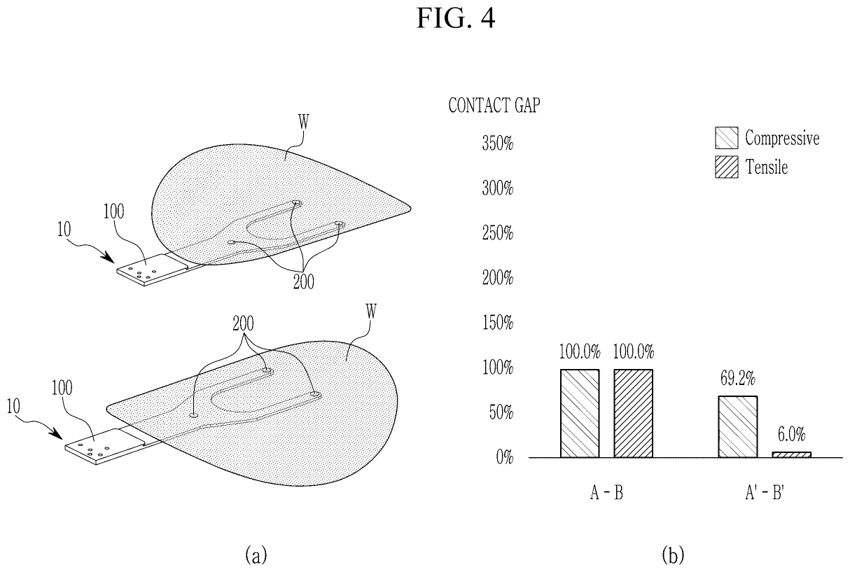

According to the above-noted arranged structure, the wafer W may be stably adsorbed when the state of the wafer W is changed due to compression and tension. Stable adsorption means that despite compression and tension of the wafer W, the wafer W does not fall off the wafer transfer device 10. The effect of adsorption will be described later with reference to FIG. 4.

The angle with the base A′ will be referred to as base angles X and Y, and Z will be referred to as an apex angle.

Regarding the wafer transfer device 10, an average angle of the base angles X and Y of the triangle configured by the arranged structure of the vacuum pad 200 may be equal to or greater than 60 degrees, and the angle of the apex angle Z may be less than 60 degrees.

According to the embodiment, it is preferable for the angle of the apex angle Z to be less than 50 degrees. When the angle of the apex angle Z is less than 50 degrees, a sum of the base angles X and Y must be equal to or greater than 130 degrees.

The triangle may be an isosceles triangle, and is not limited thereto.

FIG. 4 illustrates an adsorption effect of a wafer transfer device according to an embodiment.

FIG. 4 (a) illustrates that the wafer W is arranged in the wafer transfer device 10, showing the wafer W in a tensile state and in a compressive state adsorbed to the wafer transfer device 10.

The wafer transfer device 10 aims to stably adsorb the wafer W and transfer the same while the wafer W is bent (i.e., warpage) (or while the wafer W is compressed or tensile as shown in FIG. 4 (a)).

Two pairs of graphs shown in FIG. 4 (b) are provided to compare contact degrees (or adsorption effects) between the wafer W and the vacuum pad 200 changeable according to the compression and tension of the wafer W when the vacuum pad 200 is arranged as shown in FIG. 3 (a) and (b).

The two pairs of graphs respectively correspond to the case when the triangle in which the vacuum pad 200 is arranged has the base A and height B (or A-B) as shown in FIG. 3 (a), and the case when the triangle in which the vacuum pad 200 is arranged has the base A′ and height B′ (or A′-B′) as shown in FIG. 3b.

The mark % in the graph represents a contact gap between the raised rim 220 and the wafer W when the wafer W contacts the vacuum pad 200. The contact gap represents a size of the path for generating a vacuum leakage when a vacuum pressure is applied.

In the case of the graph A-B corresponding to FIG. 3 (a), it is found that, when the wafer W is adsorbed to the vacuum pad 200, the contact gap generated by compression and tension of the wafer W is given as 100% for the compression and the tension. That is, this signifies that the gap is generated between the vacuum pad 200 and the wafer W.

In the case of the graph A′-B′ corresponding to FIG. 3 (b), it is found that the contact gap generated by a contact is 69.2% in the case of compression and is 6% in the case of tension. That is, as shown in FIG. 3 (b), it is found that the contact gap generated at the time of contact is reduced when the first pad portion 202 is arranged so that the height B′ becomes longer than the base A′ formed by the one pair of second pad portions 204.

Regarding the wafer transfer device 10, the vacuum pad 200 arranges the vacuum pad 200 so that the base A′ formed by the one pair of second pad portions 204 may become longer than the height B′ of the triangle, as shown in FIG. 3 (b).

That is, this aims at stably adsorbing the wafer W by arranging the vacuum pad 200 to allow the height B′ to be longer than the base A′ in the triangle in which the vacuum pad 200 is arranged, when the state change caused by the compression and tension of the wafer W is generated.

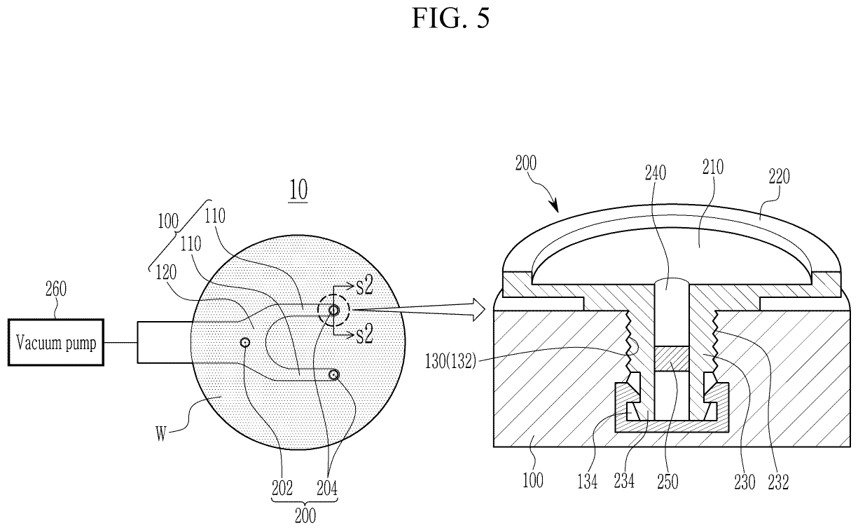

FIG. 5 illustrates an attached configuration of a vacuum pad and a blade in a wafer transfer device according to another embodiment.

The attachment of the vacuum pad 200 and the blade 100 may include a snap-fit attachment.

As shown in FIG. 5, the wafer transfer device 10 may have the structure in which a joint portion 234 is included in a second end of the attachment portion 230 of the vacuum pad 200, and a joint groove 134 is included in a second end of the internal bore 130 of the blade 100.

The joint portion 234 may be inserted into the joint groove 134 to perform a snap-fit attachment.

The snap-fit attachment shown in FIG. 5 may be an additional attachment by the joint portion 234 and the joint groove 134 while the attachment portion 230 of the vacuum pad 200 is inserted into the internal bore 130 of the blade 100. The snap-fit attachment prevents the vacuum pad 200 from easily leaving (i.e., becoming dislodged from) the blade 100.

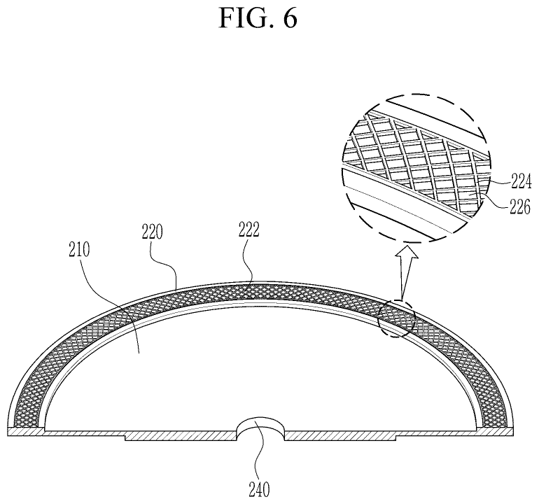

FIG. 6 illustrates a shape of raised rim of a vacuum pad in a wafer transfer device according to another embodiment.

A protruding pattern for preventing the wafer W from sliding may be included on the upper surface of the raised rim 220 of the vacuum pad 200. That is, as shown in FIG. 6, the raised rim 220 may further include a protruding wall 222 arranged on the upper surface.

The protruding wall 222 may include a first protruding portion 224 with a first height, and a second protruding portion 226 with a second height. The first protruding portion 224 may be arranged higher than the second protruding portion 226.

The first protruding portion 224 may have the shape of ‘X’ in a plan formed by the first direction and second direction, where the vacuum pad 200 is arranged. As the first protruding portions 224 is continuously connected and arranged, the pattern shown in FIG. 6 may be formed.

However, the structure of the first protruding portion 224 is not limited to what is shown in the drawings. Any structures for preventing the wafer W from sliding when contacting the wafer W may be utilized, and embodiments of the present invention are not limited to the illustrated embodiment in FIG. 6.

The worn degree of the vacuum pad 200 may be determined by comparing the height difference between the first protruding portion 224 and the second protruding portion 226 from among the protruding wall 222.

FIG. 7 illustrates a step generated by a vacuum line in a wafer transfer device, and FIG. 8 illustrates removal of a step generated by a wafer transfer device according to FIG. 7.

FIG. 7 (a) illustrates a bottom surface of the blade 100. The vacuum pad 200 may be arranged on the upper surface of the blade 100, and the vacuum path 250 may be arranged on the bottom surface thereof to pass through the vacuum pad 200. The vacuum pad 200 is arranged on the upper surface of the blade 100, but to show the arranged structure of the vacuum pad 200 and the vacuum path 250, the vacuum pad 200 is shown together.

FIG. 7 (b) illustrates the blade 100 and the vacuum path 250 in the cross-section of s3 in FIG. 7 (a).

As shown in FIG. 7 (a) and (b), the first surface of the vacuum path 250 may be installed in the blade 100 (i.e., the vacuum path is recessed within the blade 100), and the second surface thereof may be exposed on the other surface of the blade 100 (i.e., the vacuum path 250 is formed within the blade 100 and has a U-shaped configuration in cross section and is open to the external environment).

In detail, as shown in FIG. 7 (b), the tape portion 272 is arranged on the exposed portion of the vacuum path 250, and becomes the second surface of the vacuum path 250. The step as shown in FIG. 7 (b) is generated between the tape portion 272, that is, the second surface of the vacuum path 250 and the second surface of the blade 100.

According to the embodiment of the wafer transfer device 10 according to the present disclosure, as shown in FIG. 8 (a) and (b), a coated portion 270 may be further arranged on a second surface of the blade 100.

FIG. 8 (a) illustrates a bottom surface of the blade 100, and FIG. 8 (b) illustrates the blade 100 and vacuum path 250 in the cross-section of s4 in FIG. 8 (a).

As shown in FIG. 8 (b), the step shown in FIG. 7 (b) may be removed by the coated portion 270. In detail, as the coated portion 270 is arranged on the second surface of the blade 100, the step generated between the second surface of the blade 100 and the tape portion 272 disappears.

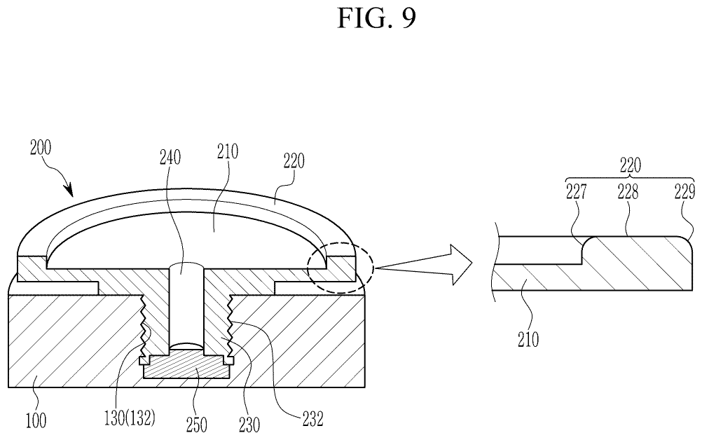

FIG. 9 illustrates a shape of raised rim including curvature in a wafer transfer device according to another embodiment.

As shown in FIG. 9, the wafer transfer device 10 may include a blade 100 with a first surface on which the wafer W is seated, and a vacuum pad 200 removably secured to the blade 100 and configured to adsorb the wafer W on the blade 100 (see FIG. 2).

The vacuum pad 200 includes a suction portion 210 for adsorbing the wafer W while spaced from the wafer W. The vacuum pad 200 may include a raised rim 220 surrounding the suction portion 210 (i.e., extending circumferentially around an outer periphery of the suction portion 210), having a first surface further protruding than a first surface of the suction portion 210, and having a curved shape; and a attachment portion 230 arranged on a center portion of the suction portion 210, and having a shape protruding to another side.

The raised rim 220 shown in FIG. 9 includes an upper surface having curvature, which is partly different from the vacuum pad 200 shown in FIG. 2. The rest of the configuration corresponds to the vacuum pad 200 of FIG. 2 so no repeated configuration will be described.

The blade 100 may include a internal bore 130 into which the attachment portion 230 is inserted such that the vacuum pad 200 and the blade 100 may be removably secured to each other.

The screw thread 232 may be arranged on the external circumference of the attachment portion 230, and the screw thread 232 may be combined to the spiral groove 132 arranged inside the internal bore 130.

Although not shown, the snap-fit configuration described with reference to FIG. 5 may be utilized in some embodiments.

Referring to FIG. 9, the upper surface of the raised rim 220 may be divided into a first seating portion 227, second seating portion 228, and third seating portion 229 with respect to the distance to the center of the vacuum pad 200 (i.e., the third seating portion 229 is radially further from the center of the vacuum pad 200 than the first seating portion 227 and the second seating portion 228, and the second seating portion 228 is located between the first seating portion 227 and the third seating portion 229).

The region disposed the nearest the center of the vacuum pad 200 may be referred to as the first seating portion 227, the region disposed the farthest the center thereof may be referred to as the third seating portion 229, and the middle region may be referred to as the second seating portion 228.

According to the embodiment, at least one of the first seating portion 227, the second seating portion 228, and the third seating portion 229 may have a different height that is a perpendicular distance from the first surface of the vacuum pad 200.

FIG. 9 illustrates an embodiment in which the height of the second seating portion 228 is greater than the heights of the first seating portion 227 and the third seating portion 229.

The first seating portion 227 and the third seating portion 229 may include curvature, and the raised rim 220 may respectively have curvature at the upper surface of the internal circumference and the upper surface of the external circumference.

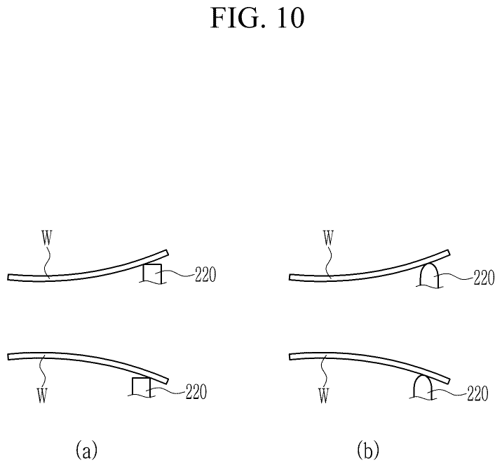

FIG. 10 illustrates a wafer adsorption effect by a wafer transfer device of FIG. 9.

FIG. 10 (a) illustrates that the wafer W contacts the raised rim 220 of the vacuum pad 200 of the wafer transfer device 10 of FIG. 2. The upper surface of the raised rim 220 shown in FIG. 10 (a) includes no curvature, and it is found that the contact area is narrow between the contact surface with the wafer W.

FIG. 10 (b) illustrates a shape of the vacuum pad 200 of the wafer transfer device 10 of FIG. 9. It is found in FIG. 10 (b) that the contact area between the wafer W and the contact surface of the raised rim 220 of the vacuum pad 200 is relatively increased, compared to the contact area in FIG. 10 (a).

According to the embodiment, the upper surface of the raised rim 220 of the vacuum pad 200 includes curvature, thereby increasing the contact area with the wafer W during the adsorption process, and increasing adsorption stability of the wafer W.

FIG. 11 illustrates a configuration of a wafer transfer system according to an embodiment.

As shown in FIG. 11, the wafer transfer system 1 includes a wafer transfer device 10 including a blade 100 with a first surface on which the wafer W is seated and a vacuum pad 200 for adsorbing the wafer W on the blade 100.

The wafer transfer system 1 may also include a core portion 20 for supporting the blade 100, and a rotation portion 30 connected to the core portion 20 for rotating the blade 100 with respect to a third direction that is perpendicular to the first direction in which the first surface of the blade 100 is arranged as an axis (see FIG. 2).

The third direction represents the direction that is perpendicular to the plane formed by the above-noted first direction and the second direction.

The blade 100 may include a pair of arm portions 110 extending in the first direction and spaced from each other and disposed in parallel, and a support portion 120 arranged on respective one sides of the one pair of arm portions 110 and connecting the one pair of arm portions 110 (see FIG. 2).

The vacuum pad 200 may include a first pad portion 202 arranged on the support portion 120, and a pair of second pad portions 204 arranged on the one pair of arm portions 110 to be arranged in a second direction that is perpendicular to the first direction (see FIG. 2).

Regarding the triangle formed by the three vacuum pads 200, the apex angle formed by setting the first pad portion 202 as a vertex has the angle of less than 50 degrees, and the vacuum pad 200 and the blade 100 are removably secured to each other by the snap-fit attachment (see FIG. 2 and FIG. 5).

The wafer transfer system 1 may further include a perpendicular moving portion 40 connected to the rotation portion 30 and ascending/descending the blade 100 in the third direction.

The wafer transfer system 1 may include a horizontal moving portion 50 connected to the rotation portion 30 and moving the blade 100 in the direction that is perpendicular to the third direction.

The wafer transfer device 10 and the wafer transfer system 1 according to the present disclosure may be used when performing a specific process on the wafer W, and transferring the wafer W to a wafer measuring device or a test device in a chamber where the process is performed. However, without being limited to the measuring device or the test device, it may be applied to the various devices for vacuum-adsorbing the wafer W and transferring the same.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

What is claimed is:

1. A wafer transfer device comprising:
a blade comprising a first surface configured to receive a wafer; and
a vacuum pad removably secured to the blade and configured to adsorb the wafer to the blade,
wherein the blade comprises:
a pair of arm portions in spaced apart, parallel relationship with each other, and
a support portion connecting the pair of arm portions,
wherein the vacuum pad comprises:
a first pad portion on the support portion, and
a pair of second pad portions, each second pad portion on a respective one of the pair of arm portions,
wherein the first pad portion and the pair of second pad portions define a triangle with the first pad portion and the pair of second pad portions as three vertexes of the triangle, and
wherein a length of a base of the triangle formed by the pair of second pad portions is less than a length of a height of the triangle.

2. The wafer transfer device of claim 1, wherein a ratio of the length of the base to the length of the height is equal to or greater than 1.4 and equal to or less than 1.8.

3. The wafer transfer device of claim 1, wherein an average angle of a base angle of the triangle is equal to or greater than 60 degrees.

4. The wafer transfer device of claim 1, wherein an angle of an apex angle excluding a base angle of the triangle is less than 60 degrees.

5. The wafer transfer device of claim 1, wherein the vacuum pad comprises a suction portion configured to adsorb the wafer,
a raised rim extending circumferentially around an outer periphery of the suction portion, wherein the suction portion comprises a first surface and an opposite second surface, and wherein the raised rim comprises a third surface that is spaced apart from the first surface of the suction portion,
an attachment portion extending outward from the suction portion second surface, and
a vacuum aperture extending through the attachment portion and in fluid communication with the suction portion.

6. The wafer transfer device of claim 5, wherein the vacuum aperture is in fluid communication with a vacuum passageway in the blade.

7. The wafer transfer device of claim 6, further comprising a vacuum pump connected to the vacuum passageway and configured to supply vacuum pressure to the vacuum aperture.

8. The wafer transfer device of claim 6, wherein the vacuum passageway is formed in the blade and comprises a portion exposed through a second surface of the blade, and wherein tape is arranged over the exposed portion of the vacuum passageway and forms steps in the second surface of the blade.

9. The wafer transfer device of claim 8, further comprising a coated portion on the second surface of the blade.

10. The wafer transfer device of claim 5, wherein the blade comprises an internal bore, and wherein the attachment portion is inserted within the internal bore to removably secure the vacuum pad to the blade.

11. The wafer transfer device of claim 10, wherein the internal bore comprises internal threads, wherein the attachment portion comprises external threads, and wherein the attachment portion is threadingly engaged with the internal bore to removably secure the vacuum pad to the blade.

12. The wafer transfer device of claim 10, wherein the internal bore comprises a circumferential groove, and wherein the attachment portion comprises a circumferential lip configured to engage the circumferential groove so as to secure the attachment portion within the internal bore with a snap-fit.

13. The wafer transfer device of claim 5, wherein the raised rim further comprises a wall on the third surface, and
wherein the wall comprises a first portion with a first height and a second portion with a second height, and wherein the first portion is higher than the second portion.

14. The wafer transfer device of claim 13, wherein the first portion has an X-shape.

15. A wafer transfer device comprising:
a blade comprising a first surface configured to receive a wafer;
a vacuum pad removably secured to the blade and configured to adsorb the wafer to the blade,
wherein the vacuum pad comprises:
a suction portion configured to adsorb the wafer,
a raised rim extending circumferentially around an outer periphery of the suction portion, wherein the suction portion comprises a first surface and an opposite second surface, and wherein the raised rim comprises a third surface that is spaced apart from the first surface of the suction portion, and
an attachment portion extending outward from the suction portion second surface, and
wherein the blade comprises:
an internal bore, and wherein the attachment portion is inserted within the internal bore to removably secure
the vacuum pad to the blade.

16. The wafer transfer device of claim 15, wherein the raised rim third surface comprises a first seating portion, a second seating portion, and a third seating portion, wherein the third seating portion is radially further from the center of the vacuum pad than the first seating portion and the second seating portion, and wherein the second seating portion is located between the first seating portion and the third seating portion, and
at least one of the first seating portion, the second seating portion, and the third seating portion, each having a respective different height relative to the vacuum pad first surface.

17. The wafer transfer device of claim 16, wherein, relative to the suction portion first surface. the second seating portion is higher than the first seating portion and the third seating portion.

18. A wafer transfer system comprising:
a wafer transfer device including a blade comprising a first surface configured to receive a wafer, and a vacuum pad configured to adsorb the wafer to the blade;
a core portion configured to support the blade; and
a rotation portion connected to the core portion,
wherein the blade comprises:
a pair of arm portions in spaced apart, parallel relationship with each other, and a support portion connecting the pair of arm portions,
wherein the vacuum pad comprises:
a first pad portion on the support portion, and a pair of second pad portions, each second pad portion on a respective one of the pair of arm portions,
wherein the first pad portion and the pair of second pad portions define a triangle with an apex angle formed with the first pad portion as a vertex and an angle of less than 50 degrees,
wherein the vacuum pad and the blade are removably secured together by a snap-fit, and
wherein the rotation portion is configured to rotate the blade.

19. The wafer transfer system of claim 18, further comprising a first moving portion connected to the rotation portion, wherein the first moving portion is configured to move the blade in a first direction.

20. The wafer transfer system of claim 18, further comprising a second moving portion connected to the rotation portion, wherein the second moving portion is configured to move the blade in a second direction that is perpendicular to the first direction.
